(19) United States
(12) Patent Application Publication
(10) Pub. No.: US 2016/0079985 A1
(43) Pub. Date: Mar. 17, 2016

(54) QUADRATURE LOCAL OSCILLATOR PHASE SYNTHESIS AND ARCHITECTURE FOR DIVIDE-BY-ODD-NUMBER FREQUENCY DIVIDERS

(71) Applicant: QUALCOMM Incorporated, San Diego, CA (US)

(72) Inventors: Yunliang ZHU, San Diego, CA (US); Kevin Hsi-huai WANG, San Diego, CA (US); Rajagopalan RANGARAJAN, San Diego, CA (US)

(21) Appl. No.: 14/487,906

(22) Filed: Sep. 16, 2014

(51) Int. Cl. H03K 23/54; H04L 27/12; H03K 21/10

(52) U.S. Cl. CPC H03K 23/544; H03K 21/10; H04L 27/122

(57) ABSTRACT

Certain aspects of the present disclosure provide techniques and apparatus for generating in-phase and quadrature (I/Q) local oscillator (LO) signals that may be synthesized using signals output from a divide-by-odd-number frequency divider (e.g., Div3 or Div5). This may be accomplished by deriving each period of the LO signal from a selected output signal of the frequency divider such that the average phase over multiple LO periods yields desired I/Q LO signals. This operation may save current because a phase interpolation circuit need not be used and moreover, provide I/Q LO signals having equal gain. Certain aspects of the present disclosure also provide a “dummy” LO signal, which may be used to in conjunction with a “dummy load” to present constant load impedance to a low noise amplifier (LNA) during time gaps (periods of an oscillating signal input to the frequency divider) in which the I/Q LO signals are all off.

### TECHNICAL FIELD

Certain aspects of the present disclosure generally relate to radio frequency (RF) electronic circuits and, more particularly, to quadrature signal generation with divide-by-odd-number frequency dividers.

### BACKGROUND

Wireless communication networks are widely deployed to provide various communication services such as telephony, video, data, messaging, broadcasts, and so on. Such networks, which are usually multiple access networks, support communications for multiple users by sharing the available network resources. For example, one network may be a 3G (the third generation of mobile phone standards and technology) system, which may provide network service via any one of various 3G radio access technologies (RATs) including EVDO (Evolution-Data Optimized), 1×RTT (1 times Radio Transmission Technology, or simply 1×), W-CDMA (Wideband Code Division Multiple Access), UMTS-TDD (Universal Mobile Telecommunications System-Time Division Duplexing), HSPA (High Speed Packet Access), GPRS (General Packet Radio Service), or EDGE (Enhanced Data rates for Global Evolution). The 3G network is a wide area cellular telephone network that evolved to incorporate high-speed internet access and video telephony, in addition to voice calls. Furthermore, a 3G network may be more established and provide larger coverage areas than other network systems. Such multiple access networks may also include code division multiple access (CDMA) systems, time division multiple access (TDMA) systems, frequency division multiple access (FDMA) systems, orthogonal frequency division multiple access (OFDMA) systems, single-carrier FDMA (SC-FDMA) networks, 3^{rd} Generation Partnership Project (3GPP) Long Term Evolution (LTE) networks, and Long Term Evolution Advanced (LTE-A) networks.

A wireless communication network may include a number of base stations that can support communication for a number of mobile stations. A mobile station (MS) may communicate with a base station (BS) via a downlink and an uplink. The downlink (or forward link) refers to the communication link from the base station to the mobile station, and the uplink (or reverse link) refers to the communication link from the mobile station to the base station. A base station may transmit data and control information on the downlink to a mobile station and/or may receive data and control information on the uplink from the mobile station.

### SUMMARY

Certain aspects of the present disclosure generally relate to quadrature signal generation using divide-by-odd-number frequency dividing circuits. Signals that are 90° (or approximately 90°) out of phase with respect to each other are often referred to as being “in quadrature.”

Certain aspects of the present disclosure provide a circuit for generating quadrature signals. The circuit generally includes a frequency divider, combination logic, and selection logic. The frequency divider is configured to frequency divide an input signal by an odd number to generate a plurality of frequency-divided signals. The combination logic is configured to logically combine two or more of the plurality of frequency-divided signals to produce: (1) a first set of one or more signals having a first magnitude and a first phase; and (2) a second set of one or more signals having a second magnitude and a second phase. The selection logic is configured to: (1) output a first signal having a first integer number of a first member in the first set of signals and a second integer number of a first member in the second set of signals, such that a ratio of the first integer number to the second integer number is approximately equal to a ratio of the second magnitude to the first magnitude; and (2) output a second signal having the first integer number of a second member in the first set of signals and the second integer number of a second member in the second set of signals, such that the second signal is in quadrature with the first signal over an interval.

According to certain aspects, the ratio of the first integer number to the second integer number approximates the ratio of the second magnitude to the first magnitude within a desired corresponding phase error.

According to certain aspects, the plurality of frequency-divided signals have different phases.

According to certain aspects, the input signal and the plurality of frequency-divided signals have 50% duty cycles.

According to certain aspects, the interval is equal to a period of the input signal multiplied with a sum of the first integer number and the second integer number.

According to certain aspects, the selection logic is further configured to output a third signal during at least one gap in the interval when nothing from the first set of signals or the second set of signals is being output.

According to certain aspects, the second member in the first set of signals is different from the first member in the first set of signals and wherein the second member in the second set of signals is different from the first member in the second set of signals.

According to certain aspects, the selection logic is further configured to: output a third signal having the first integer number of a third member in the first set of signals and a second integer number of a third member in the second set of signals, such that the first signal and the third signal form a first differential signal pair; and output a fourth signal having the first integer number of a fourth member in the first set of signals and the second integer number of a fourth member in the second set of signals, such that the second signal and the fourth signal form a second differential signal pair that is in quadrature with the first differential signal pair.

According to certain aspects, the circuit operates in an open loop manner without feedback to generate the first signal and the second signal.

According to certain aspects, the first signal and the second signal have equal gain.

According to certain aspects, the circuit further includes another frequency divider configured to frequency divide at least one of the first signal or the second signal.

According to certain aspects, the odd number is 3, 5, or 7.

Certain aspects of the present disclosure provide a method for generating quadrature signals. The method generally includes frequency dividing an input signal by an odd number to generate a plurality of frequency-divided signals; logically combining two or more of the plurality of frequency-divided signals to produce: (1) a first set of one or more signals having a first magnitude and a first phase; and (2) a second set of one or more signals having a second magnitude and a second phase; outputting a first signal having a first integer number of a first member in the first set of signals and a second integer number of a first member in the second set of signals, such that a ratio of the first integer number to the second integer number is approximately equal to a ratio of the second magnitude to the first magnitude; and outputting a second signal having the first integer number of a second member in the first set of signals and the second integer number of a second member in the second set of signals, such that the second signal is in quadrature with the first signal over an interval.

Certain aspects of the present disclosure provide an apparatus for wireless communications. The apparatus generally includes a synthesizing circuit for generating a first oscillating signal and a second oscillating signal in quadrature with the first oscillating signal, combination logic, selection logic, a first mixing circuit, and a second mixing circuit. The synthesizing circuit includes a frequency divider configured to frequency divide an input oscillating signal by an odd number to generate a plurality of frequency-divided signals. The combination logic is configured to logically combine two or more of the plurality of frequency-divided signals to produce: (1) a first set of one or more signals having a first magnitude and a first phase; and (2) a second set of one or more signals having a second magnitude and a second phase. The selection logic is configured to: (1) output the first oscillating signal having a first integer number of a first member in the first set of signals and a second integer number of a first member in the second set of signals, such that a ratio of the first integer number to the second integer number is approximately equal to a ratio of the second magnitude to the first magnitude; and (2) output the second oscillating signal having the first integer number of a second member in the first set of signals and the second integer number of a second member in the second set of signals, such that the second oscillating signal is in quadrature with the first oscillating signal over an interval. The first mixing circuit is configured to mix a radio frequency (RF) signal with the first oscillating signal to generate a first frequency converted signal for baseband processing. The second mixing circuit is configured to mix the RF signal with the second oscillating signal to generate a second frequency converted signal for baseband processing.

According to certain aspects, the apparatus further includes a third mixing circuit connected with a load, wherein the selection logic is further configured to output a third oscillating signal during at least one gap in the interval when nothing from the first set of signals or the second set of signals is being output and wherein the third mixing circuit is configured to mix the RF signal with the third oscillating signal to generate a third frequency converted signal output to the load.

Certain aspects of the present disclosure provide an apparatus for generating quadrature signals. The apparatus generally includes means for frequency dividing an input signal by an odd number to generate a plurality of frequency-divided signals; means for logically combining two or more of the plurality of frequency-divided signals to produce: (1) a first set of one or more signals having a first magnitude and a first phase; and (2) a second set of one or more signals having a second magnitude and a second phase; means for outputting a first signal having a first integer number of a first member in the first set of signals and a second integer number of a first member in the second set of signals, such that a ratio of the first integer number to the second integer number is approximately equal to a ratio of the second magnitude to the first magnitude; and means for outputting a second signal having the first integer number of a second member in the first set of signals and the second integer number of a second member in the second set of signals, such that the second signal is in quadrature with the first signal over an interval.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 illustrates an example wireless communications network in accordance with certain aspects of the present disclosure.

FIG. 2 is a block diagram of an example access point (AP) and user terminals in accordance with certain aspects of the present disclosure.

FIG. 3 is a block diagram of an example transceiver front end in accordance with certain aspects of the present disclosure.

FIG. 4 is a timing diagram illustrating generation of basis local oscillator (LO) signals in accordance with certain aspects of the present disclosure.

FIG. 5 is a timing and vector diagram illustrating generation of an in-phase LO signal (LO_I) by selecting one of the basis LO signals of FIG. 4 in each period of a frequency divider output, in accordance with certain aspects of the present disclosure.

FIG. 6 is a table representing multiple calculations of phase and phase error based on different integers for NA and NB, which represent the number of each basis LO signal for generating LO_I (or LO_Q), in accordance with certain aspects of the present disclosure.

FIG. 7 is a timing diagram illustrating generation of differential in-phase (I), quadrature (Q), and dummy LO signals, in accordance with certain aspects of the present disclosure.

FIG. 8 is a block diagram of an example open loop divide-by-three I/Q LO generator, in accordance with certain aspects of the present disclosure.

FIG. 9 is a schematic diagram of an example radio frequency front-end (RFFE) using the differential I, Q, and dummy LO signals of FIG. 7, in accordance with certain aspects of the present disclosure.

FIG. 10 is a flow diagram of example operations for generating quadrature signals using a divide-by-odd-number frequency divider, in accordance with certain aspects of the present disclosure.

### DETAILED DESCRIPTION

Various aspects of the present disclosure are described below. It should be apparent that the teachings herein may be embodied in a wide variety of forms and that any specific structure, function, or both being disclosed herein is merely representative. Based on the teachings herein, one skilled in the art should appreciate that an aspect disclosed herein may be implemented independently of any other aspects and that two or more of these aspects may be combined in various ways. For example, an apparatus may be implemented or a method may be practiced using any number of the aspects set forth herein. In addition, such an apparatus may be implemented or such a method may be practiced using other structure, functionality, or structure and functionality in addition to or other than one or more of the aspects set forth herein. Furthermore, an aspect may comprise at least one element of a claim.

The word “exemplary” is used herein to mean “serving as an example, instance, or illustration.” Any aspect described herein as “exemplary” is not necessarily to be construed as preferred or advantageous over other aspects.

The techniques described herein may be used in combination with various wireless technologies such as Code Division Multiple Access (CDMA), Orthogonal Frequency Division Multiplexing (OFDM), Time Division Multiple Access (TDMA), Spatial Division Multiple Access (SDMA), Single Carrier Frequency Division Multiple Access (SC-FDMA), Time Division Synchronous Code Division Multiple Access (TD-SCDMA), and the like. Multiple user terminals can concurrently transmit/receive data via different (1) orthogonal code channels for CDMA, (2) time slots for TDMA, or (3) sub-bands for OFDM. A CDMA system may implement IS-2000, IS-95, IS-856, Wideband-CDMA (W-CDMA), or some other standards. An OFDM system may implement Institute of Electrical and Electronics Engineers (IEEE) 802.11 (Wireless Local Area Network (WLAN)), IEEE 802.16 (Worldwide Interoperability for Microwave Access (WiMAX)), Long Term Evolution (LTE) (e.g., in TDD and/or FDD modes), or some other standards. A TDMA system may implement Global System for Mobile Communications (GSM) or some other standards. These various standards are known in the art. The techniques described herein may also be implemented in any of various other suitable wireless systems using radio frequency (RF) technology, including Global Navigation Satellite System (GNSS), Bluetooth, IEEE 802.15 (Wireless Personal Area Network (WPAN)), Near Field Communication (NFC), Small Cell, Frequency Modulation (FM), and the like.

### An Example Wireless System

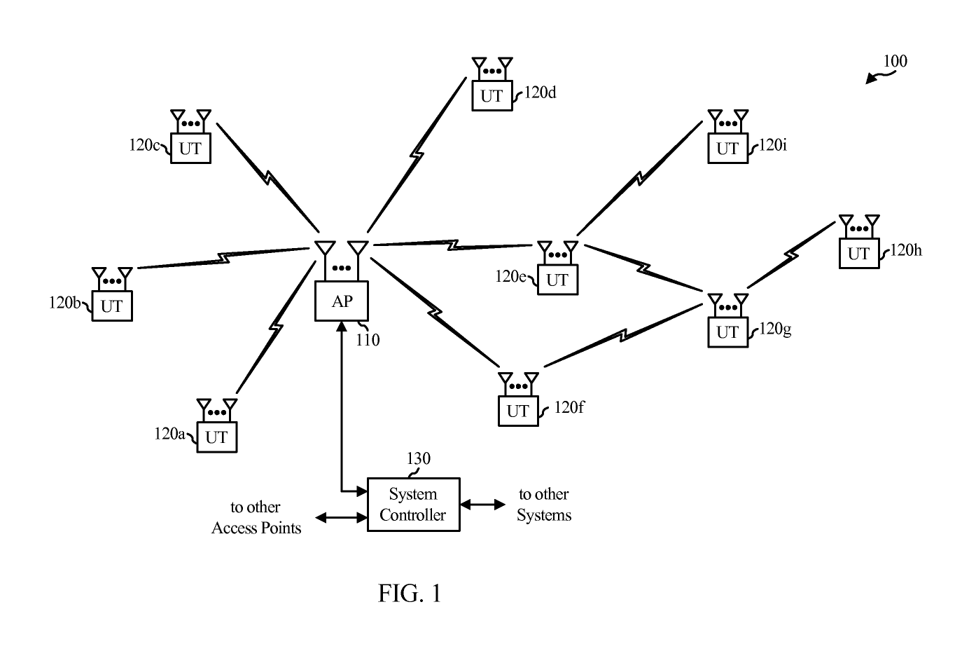

FIG. 1 illustrates a wireless communications system 100 with access points and user terminals. For simplicity, only one access point 110 is shown in FIG. 1. An access point (AP) is generally a fixed station that communicates with the user terminals and may also be referred to as a base station (BS), an evolved Node B (eNB), or some other terminology. A user terminal (UT) may be fixed or mobile and may also be referred to as a mobile station (MS), an access terminal, user equipment (UE), a station (STA), a client, a wireless device, or some other terminology. A user terminal may be a wireless device, such as a cellular phone, a personal digital assistant (PDA), a handheld device, a wireless modem, a laptop computer, a tablet, a personal computer, etc.

Access point 110 may communicate with one or more user terminals 120 at any given moment on the downlink and uplink. The downlink (i.e., forward link) is the communication link from the access point to the user terminals, and the uplink (i.e., reverse link) is the communication link from the user terminals to the access point. A user terminal may also communicate peer-to-peer with another user terminal. A system controller 130 couples to and provides coordination and control for the access points.

System 100 employs multiple transmit and multiple receive antennas for data transmission on the downlink and uplink. Access point 110 may be equipped with a number Nₐₚ of antennas to achieve transmit diversity for downlink transmissions and/or receive diversity for uplink transmissions. A set Nᵤ of selected user terminals 120 may receive downlink transmissions and transmit uplink transmissions. Each selected user terminal transmits user-specific data to and/or receives user-specific data from the access point. In general, each selected user terminal may be equipped with one or multiple antennas (i.e., Nᵤₜ≧1). The Nᵤ selected user terminals can have the same or different number of antennas.

Wireless system 100 may be a time division duplex (TDD) system or a frequency division duplex (FDD) system. For a TDD system, the downlink and uplink may share the same frequency band. For an FDD system, the downlink and uplink use different frequency bands. System 100 may also utilize a single carrier or multiple carriers for transmission. Each user terminal may be equipped with a single antenna (e.g., in order to keep costs down) or multiple antennas (e.g., where the additional cost can be supported).

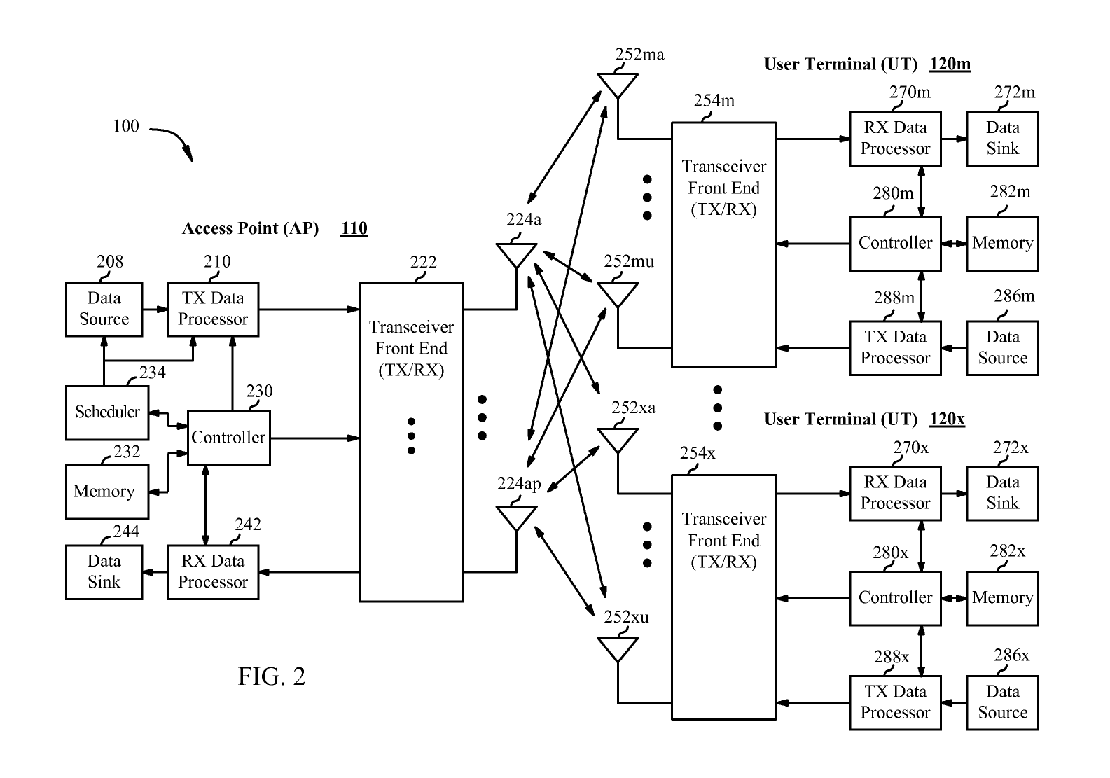

FIG. 2 shows a block diagram of access point 110 and two user terminals 120m and 120x in wireless system 100. Access point 110 is equipped with Nₐₚ antennas 224a through 224ap. User terminal 120m is equipped with N_{ut,m} antennas 252ma through 252mu, and user terminal 120x is equipped with N_{ut,x} antennas 252xa through 252xu. Access point 110 is a transmitting entity for the downlink and a receiving entity for the uplink. Each user terminal 120 is a transmitting entity for the uplink and a receiving entity for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink, Nᵤₚ user terminals are selected for simultaneous transmission on the uplink, N_{dn} user terminals are selected for simultaneous transmission on the downlink, Nᵤₚ may or may not be equal to N_{dn}, and Nᵤₚ and N_{dn} may be static values or can change for each scheduling interval. Beam-steering or some other spatial processing technique may be used at the access point and user terminal.

On the uplink, at each user terminal 120 selected for uplink transmission, a TX data processor 288 receives traffic data from a data source 286 and control data from a controller 280. TX data processor 288 processes (e.g., encodes, interleaves, and modulates) the traffic data {dᵤₚ} for the user terminal based on the coding and modulation schemes associated with the rate selected for the user terminal and provides a data symbol stream {sᵤₚ} for one of the N_{ut,m} antennas. A transceiver front end (TX/RX) 254 (also known as a radio frequency front end (RFFE)) receives and processes (e.g., converts to analog, amplifies, filters, and frequency upconverts) a respective symbol stream to generate an uplink signal. The transceiver front end 254 may also route the uplink signal to one of the N_{ut,m} antennas for transmit diversity via an RF switch, for example. The controller 280 may control the routing within the transceiver front end 254.

A number Nᵤₚ of user terminals may be scheduled for simultaneous transmission on the uplink. Each of these user terminals transmits its set of processed symbol streams on the uplink to the access point.

At access point 110, Nₐₚ antennas 224a through 224ap receive the uplink signals from all Nᵤₚ user terminals transmitting on the uplink. For receive diversity, a transceiver front end 222 may select signals received from one of the antennas 224 for processing. For certain aspects of the present disclosure, a combination of the signals received from multiple antennas 224 may be combined for enhanced receive diversity. The access point's transceiver front end 222 also performs processing complementary to that performed by the user terminal's transceiver front end 254 and provides a recovered uplink data symbol stream. The recovered uplink data symbol stream is an estimate of a data symbol stream {sᵤₚ} transmitted by a user terminal. An RX data processor 242 processes (e.g., demodulates, deinterleaves, and decodes) the recovered uplink data symbol stream in accordance with the rate used for that stream to obtain decoded data. The decoded data for each user terminal may be provided to a data sink 244 for storage and/or a controller 230 for further processing.

On the downlink, at access point 110, a TX data processor 210 receives traffic data from a data source 208 for N_{dn} user terminals scheduled for downlink transmission, control data from a controller 230 and possibly other data from a scheduler 234. The various types of data may be sent on different transport channels. TX data processor 210 processes (e.g., encodes, interleaves, and modulates) the traffic data for each user terminal based on the rate selected for that user terminal TX data processor 210 may provide a downlink data symbol streams for one of more of the N_{dn} user terminals to be transmitted from one of the Nₐₚ antennas. The transceiver front end 222 receives and processes (e.g., converts to analog, amplifies, filters, and frequency upconverts) the symbol stream to generate a downlink signal. The transceiver front end 222 may also route the downlink signal to one or more of the Nₐₚ antennas 224 for transmit diversity via an RF switch, for example. The controller 230 may control the routing within the transceiver front end 222.

At each user terminal 120, N_{ut,m} antennas 252 receive the downlink signals from access point 110. For receive diversity at the user terminal 120, the transceiver front end 254 may select signals received from one of the antennas 252 for processing. For certain aspects of the present disclosure, a combination of the signals received from multiple antennas 252 may be combined for enhanced receive diversity. The user terminal's transceiver front end 254 also performs processing complementary to that performed by the access point's transceiver front end 222 and provides a recovered downlink data symbol stream. An RX data processor 270 processes (e.g., demodulates, deinterleaves, and decodes) the recovered downlink data symbol stream to obtain decoded data for the user terminal.

Those skilled in the art will recognize the techniques described herein may be generally applied in systems utilizing any type of multiple access schemes, such as TDMA, SDMA, Orthogonal Frequency Division Multiple Access (OFDMA), CDMA, SC-FDMA, and combinations thereof.

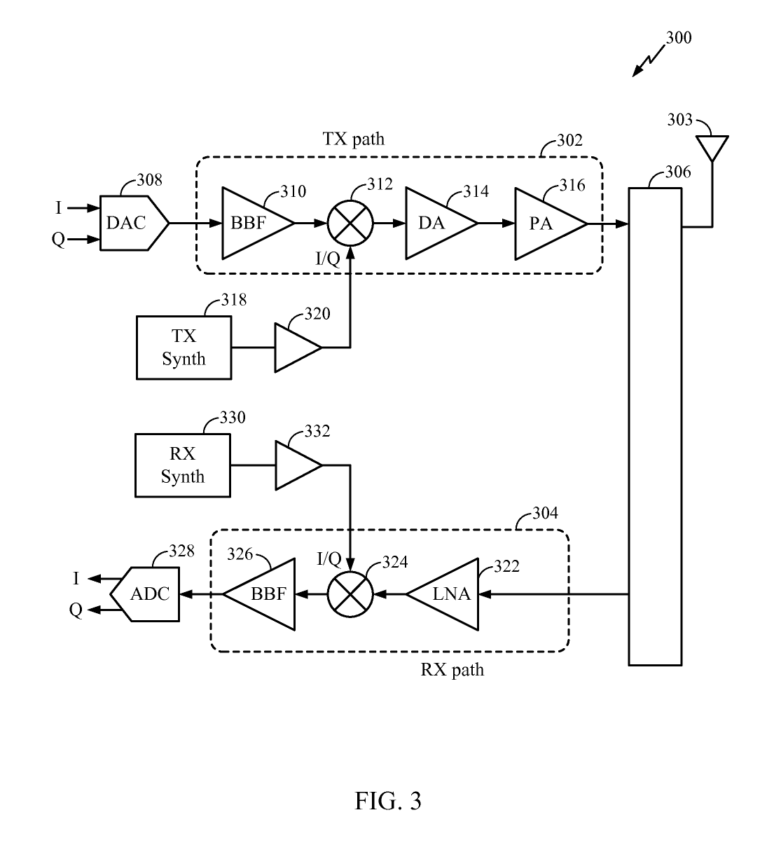

FIG. 3 is a block diagram of an example transceiver front end 300, such as transceiver front ends 222, 254 in FIG. 2, in accordance with certain aspects of the present disclosure. The transceiver front end 300 includes a transmit (TX) path 302 (also known as a transmit chain) for transmitting signals via one or more antennas and a receive (RX) path 304 (also known as a receive chain) for receiving signals via the antennas. When the TX path 302 and the RX path 304 share an antenna 303, the paths may be connected with the antenna via an interface 306, which may include any of various suitable RF devices, such as a duplexer, a switch, a diplexer, and the like.

Receiving in-phase (I) or quadrature (Q) baseband analog signals from a digital-to-analog converter (DAC) 308, the TX path 302 may include a baseband filter (BBF) 310, a mixer 312, a driver amplifier (DA) 314, and a power amplifier 316. The BBF 310, the mixer 312, and the DA 314 may be included in a radio frequency integrated circuit (RFIC), while the PA 316 is often external to the RFIC. The BBF 310 filters the baseband signals received from the DAC 308, and the mixer 312 mixes the filtered baseband signals with a transmit local oscillator (LO) signal to convert the baseband signal of interest to a different frequency (e.g., upconvert from baseband to RF). This frequency conversion process produces the sum and difference frequencies of the LO frequency and the frequency of the signal of interest. The sum and difference frequencies are referred to as the beat frequencies. The beat frequencies are typically in the RF range, such that the signals output by the mixer 312 are typically RF signals, which are amplified by the DA 314 and by the PA 316 before transmission by the antenna 303.

The RX path 304 includes a low noise amplifier (LNA) 322, a mixer 324, and a baseband filter (BBF) 326. The LNA 322, the mixer 324, and the BBF 326 may be included in a radio frequency integrated circuit (RFIC), which may or may not be the same RFIC that includes the TX path components. RF signals received via the antenna 303 may be amplified by the LNA 322, and the mixer 324 mixes the amplified RF signals with a receive local oscillator (LO) signal to convert the RF signal of interest to a different baseband frequency (i.e., downconvert). The baseband signals output by the mixer 324 may be filtered by the BBF 326 before being converted by an analog-to-digital converter (ADC) 328 to digital I or Q signals for digital signal processing.

While it is desirable for the output of an LO to remain stable in frequency, tuning to different frequencies indicates using a variable-frequency oscillator, which involves compromises between stability and tunability. Contemporary systems employ frequency synthesizers with a voltage-controlled oscillator (VCO) to generate a stable, tunable LO with a particular tuning range. Thus, the transmit LO is typically produced by a TX frequency synthesizer 318, which may be buffered or amplified by amplifier 320 before being mixed with the baseband signals in the mixer 312. Similarly, the receive LO is typically produced by an RX frequency synthesizer 330, which may be buffered or amplified by amplifier 332 before being mixed with the RF signals in the mixer 324.

### Example Quadrature LO Phase Synthesis for Divide-by-Odd-Number Frequency Dividers

Divide-by-odd-number frequency dividers are often used for LO spur dodging which is useful for carrier aggregation (CA)-enabled RF transceivers. However, divide-by-odd-number frequency dividers do not naturally produce 90° phase difference between I and Q channels. Thus, phase interpolation methods (e.g., involving high frequency delay-locked loops) may be used to generate the quadrature (I/Q) LO signals. However, these methods of generating the quadrature LO signals may have low output current capability and high total area occupied by the I/Q LO generation circuit. Moreover, the interpolation range may be limited due to high phase noise (PN) at the edge of the tuning range. In addition, phase interpolation accuracy may not be sufficient to meet stringent residual sideband (RSB) specifications due to, for example, operational amplifier (op amp) offset.

For example, a divide-by-three (Div3) frequency divider may generate output signals with 60° phase shift and 50% duty cycle. Thus, quadrature signals are not naturally available from edges of the VCO signals. A delay-locked loop may be incorporated to generate 90° phase shift from the available 60° phase-shifted signals. However, delay lines running at the LO frequency consume a large amount of current and degrade phase noise. Moreover, feedback loops may consume a large amount of real estate on the chip.

Accordingly, what is needed is a divide-by-odd-number frequency divider that reduces the area occupied by the frequency synthesizer while reducing current consumption and increasing interpolation range and phase accuracy. Therefore, certain aspects of the present disclosure provide techniques and apparatus for generating quadrature (I/Q) LO signals that may be synthesized using signals output from divide-by-odd-number frequency dividers. This may be accomplished by approximating I/Q LO phases on average over multiple LO periods such that quadrature phase properties can be asymptotically approximated with simple solutions. Such techniques provide I/Q LO signals having equal gain. Moreover, this operation may save current because a phase interpolation circuit need not be used.

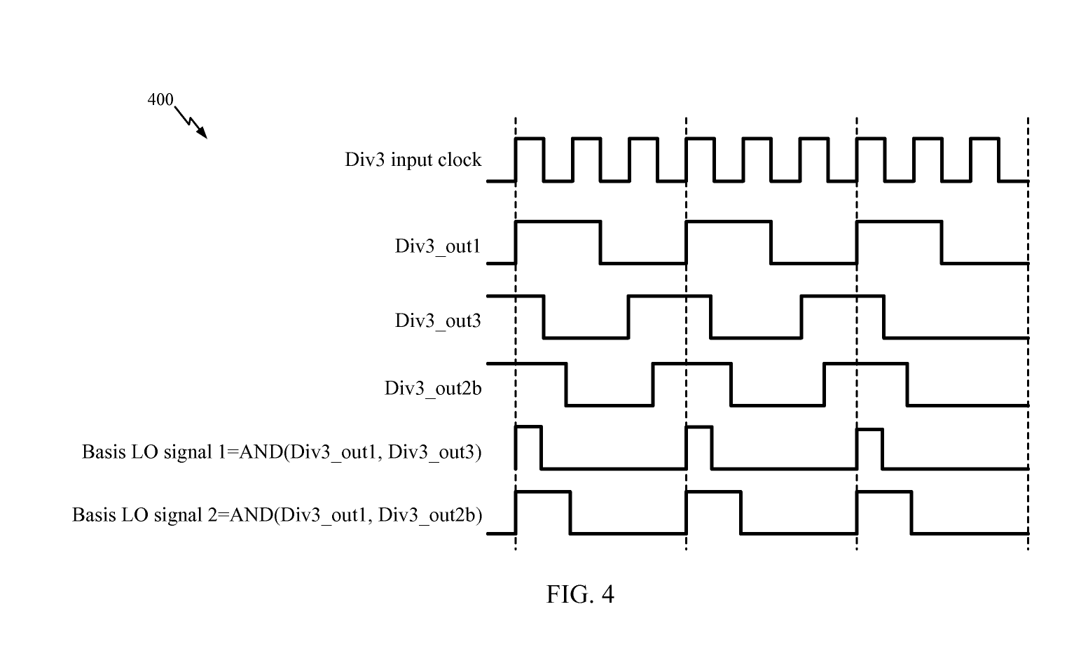

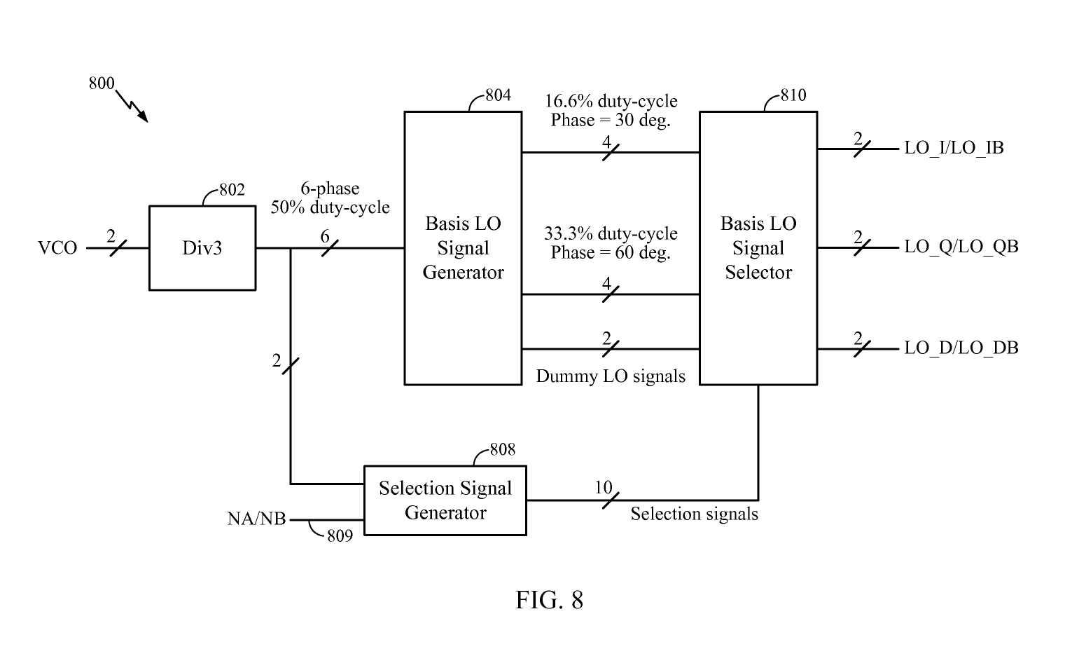

A VCO (e.g., in the RX frequency synthesizer 330 of FIG. 3) may provide an oscillating input signal, having 50% duty cycle, to a divide-by-odd-number frequency divider, which will be described in more detail below. From the divide-by-odd-number frequency divider, a set of basis LO signals may be defined as illustrated in a timing diagram 400 in FIG. 4. For example, a Div3 frequency divider (e.g., 802 in FIG. 8) may receive the oscillating input signal (Div3 input clock) and provide six output signals (three differential signals) having 50% duty cycle, yet with different relative phases. FIG. 4 illustrates three of the six outputs from the Div3 frequency divider, represented as Div3_out1, Div3_out3, and Div3_out2b (inverse of Div3_out2, which is not illustrated, along with Div3_out1b and Div3_out3b). These frequency-divided outputs may then be used to generate basis LO signals (explained below) by using digital logic such as AND gates. For example, basis LO signal 1 (otherwise referred to as LO_I1) may be generated based on the logic operation Div3_out1 AND Div3_out3. Similarly, basis LO signal 2 (otherwise referred to as LO_I2) may be generated based on the logic operation (Div3_out1 AND Div3_out2b).

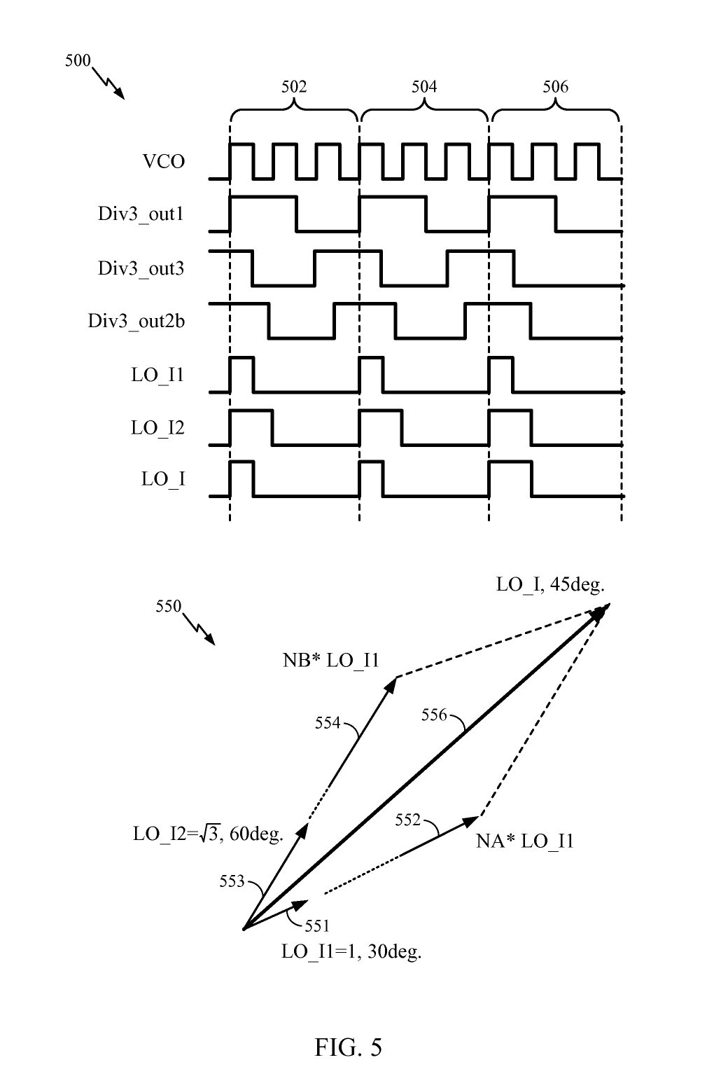

FIG. 5 illustrates basis LO signal vectors LO_I1 551 and LO_I2 553 on a vector diagram 550 and a corresponding vector sum 556, as will be described in more detail below. For example, LO_I1 may have a magnitude of 1 with a 30° phase (illustrated by vector LO_I1 551) while LO_I2 may have a magnitude of \sqrt{3} with a 60° phase (illustrated by vector LO_I2 553). The vector sum 556 of the basis LO signals over multiple periods may be used to derive an in-phase LO signal (LO_I). For example, for each period—as defined by an output signal of the Div3 frequency divider (e.g., Div3_out1)—one of the basis LO signals (e.g., one of LO_I1 or LO_I2) is selected for the corresponding period of LO_I such that the vector sum 556 of one or more basis LO signal vectors 551, 553 will have a phase equal to (or at least approximating) 45°, as will LO_I in the time domain over multiple LO periods. In other words, by selecting either LO_I1 or LO_I2 in each of multiple periods of a Div3 output signal designated as a reference, the resulting LO_I will have a 45° phase.

The timing diagram 500 illustrates an example derivation of the in-phase LO signal (LO_I), where LO_I is generated by selecting LO_I1 in the first and second periods 502, 504 of the Div3 output reference signal (here, Div3_out1) and by selecting LO_I2 in the third period 506. Thus, LO_I is the vector sum 556 of vector NA×LO_I1 552 and vector NB×LO_I2 554 where NA is an integer number of vectors LO_I1 551 and NB is an integer number of vectors LO_I2 553. NA and NB may be determined by, for example, the following equation:

$$\frac{NA}{NB} = \frac{mag ( LO\_I 1 )}{mag ( LO\_I 2 )}$$

such that the phase of LO_I will be approximately 45°, where mag(•) is the magnitude of the signal in parentheses.

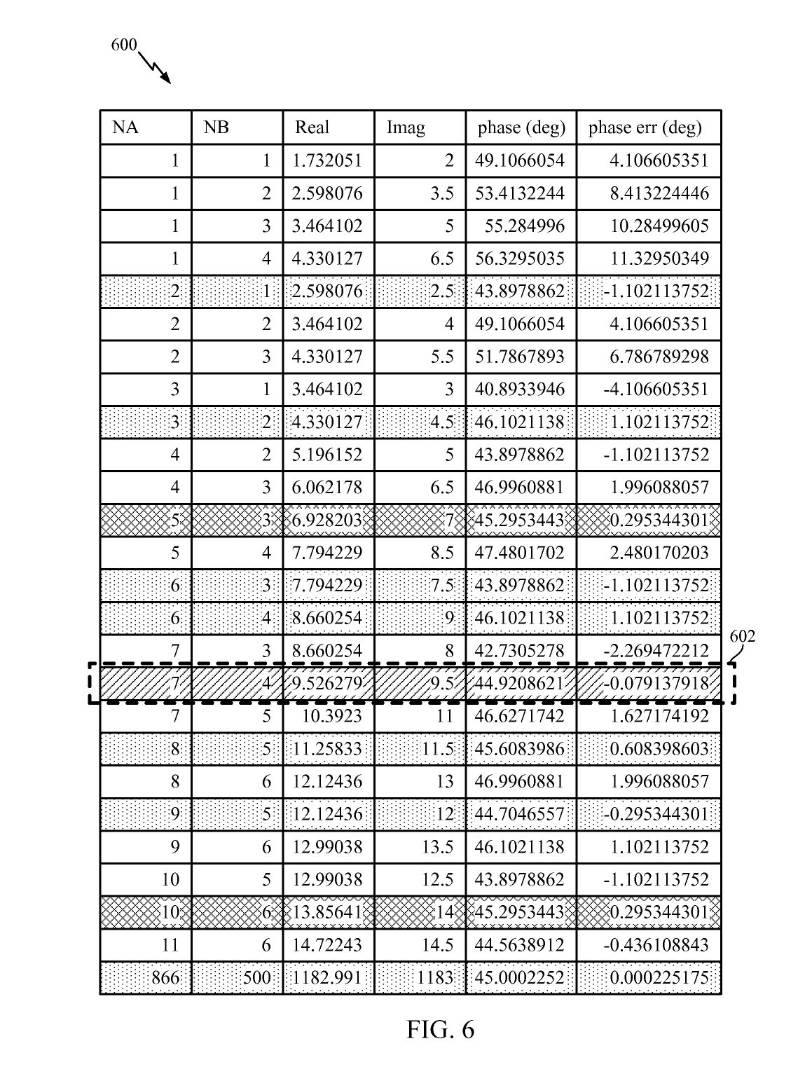

FIG. 6 shows a table 600 of calculations based on different combinations of NA and NB. For each combination, the magnitudes of the corresponding real and imaginary parts of LO_I are presented together with the resulting phase (in degrees) and phase error values (in degrees). The phase error equals the resulting phase minus the ideal phase of 45°. For example, where NA=2 and NB=1, a phase error of 1.1° is calculated for LO_I (2.2° total phase error for I/Q LO (effectively LO_I phase error×2)). Although a lower phase error may be obtained with higher integers for NA and NB (e.g., NA=866 and NB=500 may result in an I/Q phase error of roughly 0.0004°), there exists a tradeoff between lowering the phase error and degrading the performance of the system. In other words, the smallest number of integers (NA and NB) may be chosen that still meets an acceptable maximum phase error limit. For example, an NA value of 7 and NB value of 4 may be chosen as an example preferred configuration 602 to provide a total I/Q phase error of roughly 0.16° (LO_I phase error of 0.08° effectively multiplied by 2).

For certain aspects, the combination of two LO_I1 signals and one LO_I2 signal shown in the timing diagram 500 of FIG. 5 may be repeated in subsequent three-period intervals using the same pattern of two LO_I1 signals in the first two periods followed by one LO_I2 signal in a subsequent third period. In other aspects, a different pattern may be used, especially in basis LO signal combinations using higher NA and NB integers. For certain aspects, one interval of multiple frequency divider periods may use a particular pattern of basis LO signals, and a subsequent interval may use a different pattern.

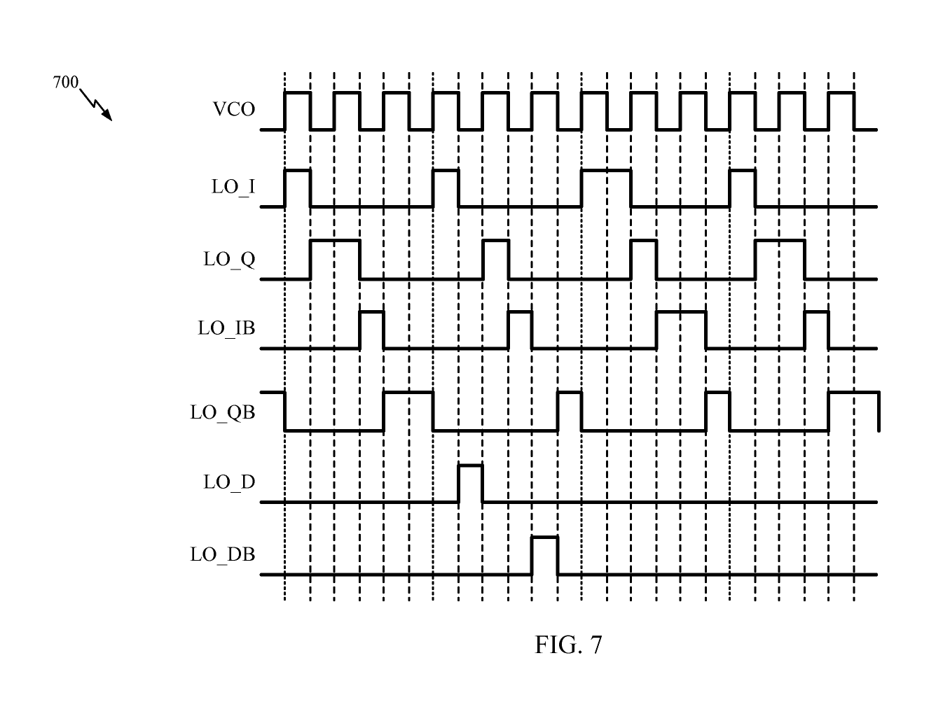

As presented in FIG. 7, the quadrature signal LO_Q, which is ideally 90° out of phase with LO_I, (i.e., phase≅135°) may be derived in a similar manner. LO_Q may have the same numbers (NA and NB) of each basis LO signal selected as LO_I in order to achieve equal gain. Moreover, as illustrated in the timing diagram 700 of FIG. 7, LO_IB (inverse LO_I) and LO_QB (inverse LO_Q) for differential I/Q LO signals may be derived in a similar manner as presented above.

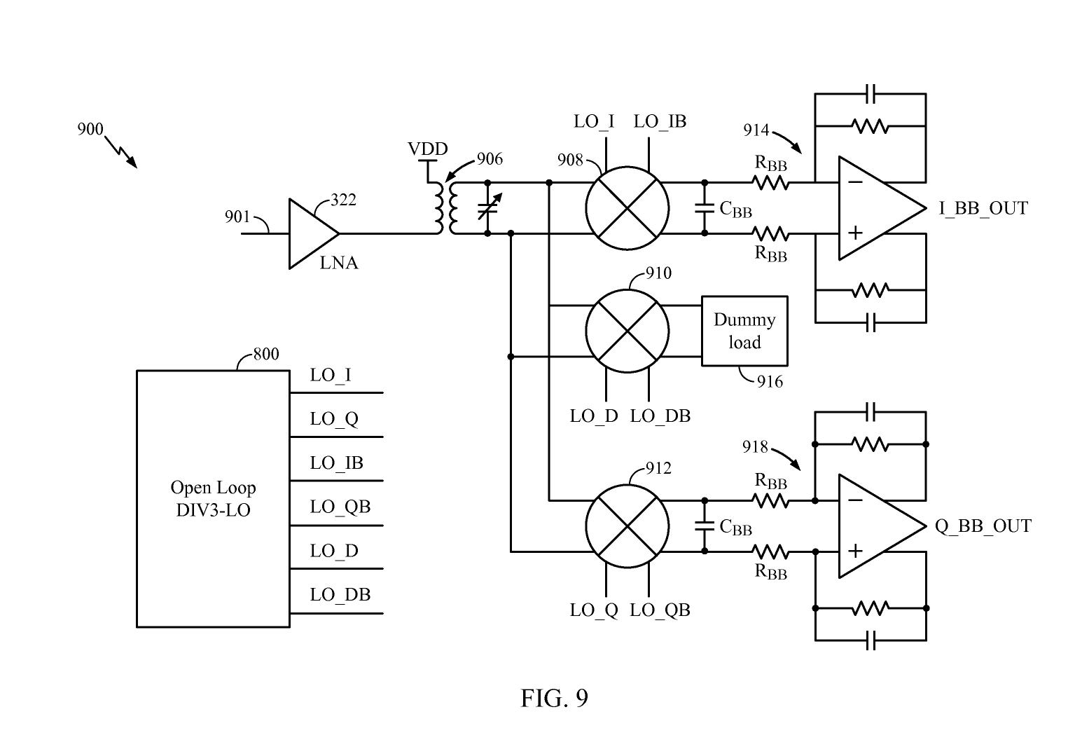

To enhance RX performance, a constant load impedance may be obtained using a “dummy” LO signal (LO_D and LO_DB). For example, as illustrated in FIG. 7, LO_D and LO_DB may be generated to fill any gaps in the LO signal (e.g., periods of the VCO oscillating signal in which the LO LO_IB, LO_Q, and LO_QB signals are all off, or logic low). Thus, the “dummy” LO signal may be used in conjunction with a “dummy” mixer and a “dummy” load 916 to load the LNA 322 (as shown in FIG. 9) during periods in which the I/Q signals (LO_I and LO_Q) are all off and ensure constant current output from the LNA 322, thus, increasing performance of the RX path 304.

### Example Implementation of Quadrature LO Phase Synthesis Using Divide-by-Odd-Number Frequency Dividers

FIG. 8 is a block diagram of an example open loop Div3 I/Q LO generator 800 in accordance with certain aspects of the present disclosure. As illustrated in FIG. 8, a divide-by-three (Div3) frequency divider 802 may receive a differential clock signal from a VCO, for example. In certain aspects, the clock input may be single-ended, as opposed to differential. The frequency divider 802 may output six signals having a 50% duty cycle and different relative phases to a basis LO signal generator 804 (e.g., comprising AND gates or the logical equivalent). The frequency divider 802 may also output any two of the six signals to a selection signal generator 808 for synchronization. The selection signal generator 808 may also receive inputs NA/NB 809 (e.g., from a processor such as the RX data processor 270 or the controller 280 of FIG. 2), which specify the numbers (NA and NB) of different basis LO signals to be selected to generate the I/Q LO signals, based on which, the selection signal generator 808 outputs ten selection signals to a basis LO signal selector 810 (e.g., a multiplexer). The basis LO signal generator 804 may derive (through logic operations) and output 4 basis LO signals (LO_I1, LO_Q1, and inverses of the same) having a 16.6% duty cycle (30° phase), four basis signals (LO_I2, LO_Q2, and inverses of the same) having a 33.3% duty cycle (60° phase), and two “dummy” LO signals (LO_D and its inverse LO_DB) to the basis LO signal selector 810. The basis LO signal selector 810 may, based on the selection signals from the selection signal generator 808, select each basis LO signal in an effort to generate the (differential) LO_I, LO_Q, and LO_D signals for each period of a reference signal output by the Div3 frequency divider 802 (e.g., Div3_out1 in FIG. 5).

FIG. 9 is a schematic diagram of an example radio frequency front-end (RFFE) 900 implementing the I/Q LO generator 800 in accordance with certain aspects of the present disclosure. An input RF signal 901 (e.g., received from the antenna 303) may be amplified, buffered, or attenuated by a low noise amplifier (LNA) 322 before being sent to an in-phase (I) mixer 908, a “dummy” mixer 910, and a quadrature (Q) mixer 912. The LNA 322 may be a transconductance amplifier configured to receive an input voltage and generate an output current. The LNA 322 may output a single-ended signal or differential signals. If the output of the LNA 322 is a differential signal, the mixers 908, 910, and 912 may be double-balanced mixers. If the output of the LNA 322 is a single-ended signal, however, the mixers 908, 910, and 912 may be single-balanced mixers. A transformer 906 may be used to convert a single-ended LNA output to a differential signal.

The output signal from the LNA 322 may be mixed by the I mixer 908 with an in-phase LO (e.g., differential signals LO_I and LO_IB) to produce an output in-phase signal having frequencies at the sum and difference of the RF frequency and LO_I frequency. Similarly, the output signal from the LNA 322 may also be mixed by the Q mixer 912 with a quadrature LO (LO_Q, which is ideally 90° out of phase with LO_I) to produce an output quadrature signal having frequencies at the sum and difference of the RF frequency and LO_Q frequency. The output I and Q signals from the I mixer 908 and Q mixer 912 may be filtered through baseband filters 914, 918 to provide an in-phase baseband output (I_BB_OUT) and quadrature baseband output (Q_BB_OUT), respectively. Furthermore, the “dummy” mixer 910 may mix the output signal from the LNA 322 with the differential LO_D and LO_DB signals and send the result to a “dummy” load 916 to present constant load impedance to the LNA 322 as described above. The LO inputs to each mixer 908, 910, and 912 may be provided by a divide-by-odd-number frequency divider, such as the open loop Div3 frequency divider 800 of FIG. 8.

### Example Operations for Generating Quadrature LO Signals

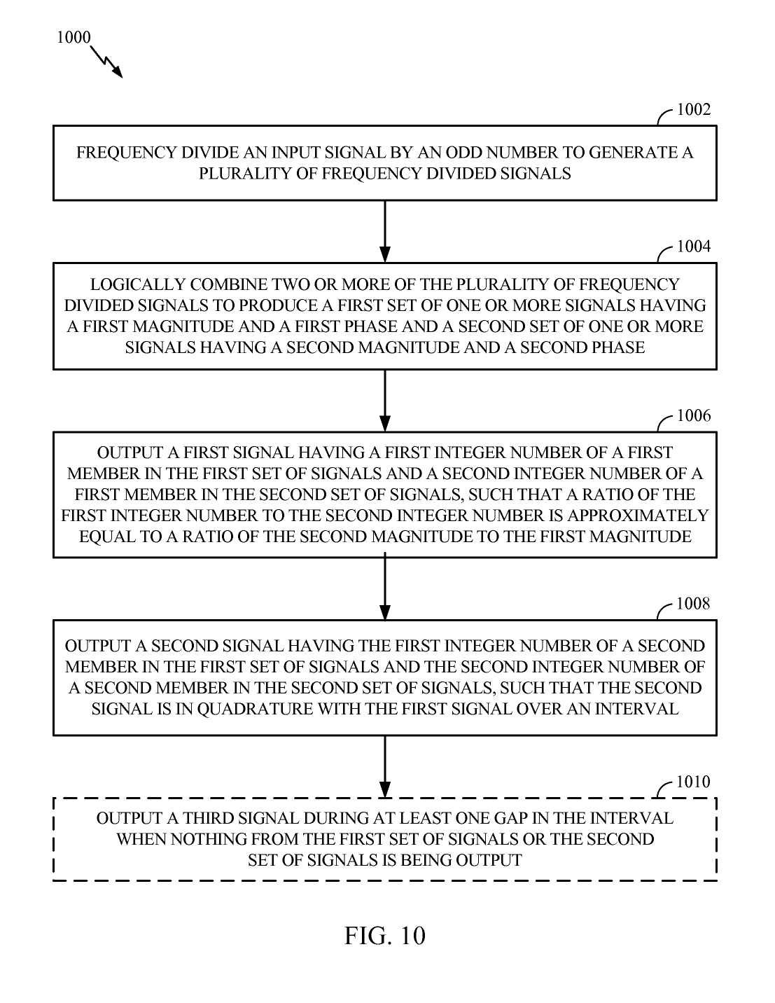

FIG. 10 illustrates example operations 1000 for generating quadrature signals, according to certain aspects of the present disclosure. The operations 1000 may be performed by a circuit, such as the open loop Div3 I/Q LO generator 800 of FIG. 8. The operations 1000 may begin at block 1002 by frequency dividing an input signal by an odd number to generate a plurality of frequency-divided signals. The odd number may be 3, 5, 7, etc.

At block 1004, the circuit may logically combine two or more of the plurality of frequency-divided signals to produce a first set of one or more signals having a first magnitude and a first phase and a second set of one or more signals having a second magnitude and a second phase.

At block 1006, the circuit may output a first signal having a first integer number (e.g., NA) of a first member in the first set of signals and a second integer number (e.g., NB) of a first member in the second set of signals, such that a ratio of the first integer number to the second integer number is approximately equal to a ratio of the second magnitude to the first magnitude. According to certain aspects, the ratio of the first integer number to the second integer number approximates the ratio of the second magnitude to the first magnitude within a desired corresponding phase error (e.g., less than or equal to 2°, 1°, 0.5°, 0.1°, etc.). For example, as described above with respect to table 600 in FIG. 6, the smallest number of integers (NA and NB) may be chosen that still meets an acceptable maximum phase error limit. As an example, the two ratios being approximately equal may refer to the ratio of the first integer number to the second integer number being within 20% (and preferably within 15%, 10%, 5%, 1%, or lower) of the ratio of the second magnitude to the first magnitude. However, it is the phase error corresponding to the first and second integer numbers meeting the desired phase error limit that is more important.

At block 1008, the circuit may output a second signal having the first integer number of a second member in the first set of signals and the second integer number of a second member in the second set of signals, such that the second signal is in quadrature with the first signal over an interval.

At block 1010, the circuit may optionally output a third signal during at least one gap in the interval when nothing from the first set of signals or the second set of signals is being output.

According to certain aspects, the plurality of frequency-divided signals have different phases.

According to certain aspects, the input signal and the plurality of frequency-divided signals have 50% duty cycles.

According to certain aspects, the interval is equal to a period of the input signal multiplied with a sum of the first integer number and the second integer number.

According to certain aspects, the second member in the first set of signals is different from the first member in the first set of signals. Also, the second member in the second set of signals may be different from the first member in the second set of signals.

According the certain aspects, the circuit may output a third signal having the first integer number of a third member in the first set of signals and a second integer number of a third member in the second set of signals, such that the first signal and the third signal form a first differential signal pair; and output a fourth signal having the first integer number of a fourth member in the first set of signals and the second integer number of a fourth member in the second set of signals, such that the second signal and the fourth signal form a second differential signal pair that is in quadrature with the first differential signal pair.

According to certain aspects, the first signal and the second signal are generated in an open loop manner without feedback.

According to certain aspects, the first signal and the second signal have equal gain.

According to certain aspects, the circuit frequency divides at least one of the first signal or the second signal.

The various operations or methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components with similar numbering.

For example, means for transmitting may comprise a transmitter (e.g., the transceiver front end 254 of the user terminal 120 depicted in FIG. 2 or the transceiver front end 222 of the access point 110 shown in FIG. 2) and/or an antenna (e.g., the antennas 252ma through 252mu of the user terminal 120m portrayed in FIG. 2 or the antennas 224a through 224ap of the access point 110 illustrated in FIG. 2). Means for receiving may comprise a receiver (e.g., the transceiver front end 254 of the user terminal 120 depicted in FIG. 2 or the transceiver front end 222 of the access point 110 shown in FIG. 2) and/or an antenna (e.g., the antennas 252ma through 252mu of the user terminal 120m portrayed in FIG. 2 or the antennas 224a through 224ap of the access point 110 illustrated in FIG. 2). Means for processing or means for determining may comprise a processing system, which may include one or more processors, such as the RX data processor 270, the TX data processor 288, and/or the controller 280 of the user terminal 120 illustrated in FIG. 2. Means for frequency dividing may comprise a frequency dividing circuit (e.g., the Div3 frequency divider 802). Means for logically combining may comprise a circuit having logic operations, such as AND gates (e.g., the basis LO signal generator 804). Means for outputting a signal may comprise a selection circuit, such as a multiplexer (e.g., the basis LO signal selector 810).

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logical blocks, modules and circuits described in connection with the present disclosure may be implemented or performed with a general purpose processor, a digital signal processor (DSP), an application specific integrated circuit (ASIC), a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a wireless node. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The network adapter may be used to implement the signal processing functions of the PHY layer. In the case of a user terminal 120 (see FIG. 1), a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The processing system may be configured as a general-purpose processing system with one or more microprocessors providing the processor functionality and external memory providing at least a portion of the machine-readable media, all linked together with other supporting circuitry through an external bus architecture. Alternatively, the processing system may be implemented with an ASIC (Application Specific Integrated Circuit) with the processor, the bus interface, the user interface in the case of an access terminal), supporting circuitry, and at least a portion of the machine-readable media integrated into a single chip, or with one or more FPGAs (Field Programmable Gate Arrays), PLDs (Programmable Logic Devices), controllers, state machines, gated logic, discrete hardware components, or any other suitable circuitry, or any combination of circuits that can perform the various functionality described throughout this disclosure. Those skilled in the art will recognize how best to implement the described functionality for the processing system depending on the particular application and the overall design constraints imposed on the overall system.

It is to be understood that the claims are not limited to the precise configuration and components illustrated above. Various modifications, changes and variations may be made in the arrangement, operation and details of the methods and apparatus described above without departing from the scope of the claims.

What is claimed is:

1. A method for generating quadrature signals, comprising:
frequency dividing an input signal by an odd number to generate a plurality of frequency-divided signals;
logically combining two or more of the plurality of frequency-divided signals to produce:
a first set of one or more signals having a first magnitude and a first phase; and
a second set of one or more signals having a second magnitude and a second phase;
outputting a first signal having a first integer number of a first member in the first set of signals and a second integer number of a first member in the second set of signals, such that a ratio of the first integer number to the second integer number is approximately equal to a ratio of the second magnitude to the first magnitude; and
outputting a second signal having the first integer number of a second member in the first set of signals and the second integer number of a second member in the second set of signals, such that the second signal is in quadrature with the first signal over an interval.

2. The method of claim 1, wherein the ratio of the first integer number to the second integer number approximates the ratio of the second magnitude to the first magnitude within a desired corresponding phase error.

3. The method of claim 1, wherein the plurality of frequency-divided signals have different phases.

4. The method of claim 1, wherein the input signal and the plurality of frequency-divided signals have 50% duty cycles.

5. The method of claim 1, wherein the interval is equal to a period of the input signal multiplied with a sum of the first integer number and the second integer number.

6. The method of claim 1, further comprising outputting a third signal during at least one gap in the interval when nothing from the first set of signals or the second set of signals is being output.

7. The method of claim 1, wherein the second member in the first set of signals is different from the first member in the first set of signals and wherein the second member in the second set of signals is different from the first member in the second set of signals.

8. The method of claim 1, further comprising
outputting a third signal having the first integer number of a third member in the first set of signals and a second integer number of a third member in the second set of signals, such that the first signal and the third signal form a first differential signal pair; and
outputting a fourth signal having the first integer number of a fourth member in the first set of signals and the second integer number of a fourth member in the second set of signals, such that the second signal and the fourth signal form a second differential signal pair that is in quadrature with the first differential signal pair.

9. The method of claim 1, wherein the first signal and the second signal are generated in an open loop manner without feedback.

10. The method of claim 1, wherein the first signal and the second signal have equal gain.

11. The method of claim 1, further comprising frequency dividing at least one of the first signal or the second signal.

12. The method of claim 1, wherein the odd number is 3, 5, or 7.

13. A circuit for generating quadrature signals, comprising:
a frequency divider configured to frequency divide an input signal by an odd number to generate a plurality of frequency-divided signals;
combination logic configured to logically combine two or more of the plurality of frequency-divided signals to produce:
a first set of one or more signals having a first magnitude and a first phase; and
a second set of one or more signals having a second magnitude and a second phase; and
selection logic configured to:
output a first signal having a first integer number of a first member in the first set of signals and a second integer number of a first member in the second set of signals, such that a ratio of the first integer number to the second integer number is approximately equal to a ratio of the second magnitude to the first magnitude; and
output a second signal having the first integer number of a second member in the first set of signals and the second integer number of a second member in the second set of signals, such that the second signal is in quadrature with the first signal over an interval.

14. The circuit of claim 13, wherein the ratio of the first integer number to the second integer number approximates the ratio of the second magnitude to the first magnitude within a desired corresponding phase error.

15. The circuit of claim 13, wherein the plurality of frequency-divided signals have different phases.

16. The circuit of claim 13, wherein the input signal and the plurality of frequency-divided signals have 50% duty cycles.

17. The circuit of claim 13, wherein the interval is equal to a period of the input signal multiplied with a sum of the first integer number and the second integer number.

18. The circuit of claim 13, wherein the selection logic is further configured to output a third signal during at least one gap in the interval when nothing from the first set of signals or the second set of signals is being output.

19. The circuit of claim 13, wherein the second member in the first set of signals is different from the first member in the first set of signals and wherein the second member in the second set of signals is different from the first member in the second set of signals.

20. The circuit of claim 13, wherein the selection logic is further configured to:
output a third signal having the first integer number of a third member in the first set of signals and a second integer number of a third member in the second set of signals, such that the first signal and the third signal form a first differential signal pair; and
output a fourth signal having the first integer number of a fourth member in the first set of signals and the second integer number of a fourth member in the second set of signals, such that the second signal and the fourth signal form a second differential signal pair that is in quadrature with the first differential signal pair.

21. The circuit of claim 13, wherein the circuit operates in an open loop manner without feedback to generate the first signal and the second signal.

22. The circuit of claim 13, wherein the first signal and the second signal have equal gain.

23. The circuit of claim 13, further comprising another frequency divider configured to frequency divide at least one of the first signal or the second signal.

24. The circuit of claim 13, wherein the odd number is 3, 5, or 7.

25. An apparatus for wireless communications, comprising:
a synthesizing circuit for generating a first oscillating signal and a second oscillating signal in quadrature with the first oscillating signal, the synthesizing circuit comprising:
a frequency divider configured to frequency divide an input oscillating signal by an odd number to generate a plurality of frequency-divided signals;
combination logic configured to logically combine two or more of the plurality of frequency-divided signals to produce:
a first set of one or more signals having a first magnitude and a first phase; and
a second set of one or more signals having a second magnitude and a second phase; and
selection logic configured to:
output the first oscillating signal having a first integer number of a first member in the first set of signals and a second integer number of a first member in the second set of signals, such that a ratio of the first integer number to the second integer number is approximately equal to a ratio of the second magnitude to the first magnitude; and
output the second oscillating signal having the first integer number of a second member in the first set of signals and the second integer number of a second member in the second set of signals, such that the second oscillating signal is in quadrature with the first oscillating signal over an interval;
a first mixing circuit configured to mix a radio frequency (RF) signal with the first oscillating signal to generate a first frequency converted signal for baseband processing; and
a second mixing circuit configured to mix the RF signal with the second oscillating signal to generate a second frequency converted signal for baseband processing.

26. The apparatus of claim 25, further comprising a third mixing circuit connected with a load, wherein the selection logic is further configured to output a third oscillating signal during at least one gap in the interval when nothing from the first set of signals or the second set of signals is being output and wherein the third mixing circuit is configured to mix the RF signal with the third oscillating signal to generate a third frequency converted signal output to the load.

27. A circuit for generating quadrature signals, comprising:
means for frequency dividing an input signal by an odd number to generate a plurality of frequency-divided signals;
means for logically combining two or more of the plurality of frequency-divided signals to produce:
a first set of one or more signals having a first magnitude and a first phase; and
a second set of one or more signals having a second magnitude and a second phase;
means for outputting a first signal having a first integer number of a first member in the first set of signals and a second integer number of a first member in the second set of signals, such that a ratio of the first integer number to the second integer number is approximately equal to a ratio of the second magnitude to the first magnitude; and
means for outputting a second signal having the first integer number of a second member in the first set of signals and the second integer number of a second member in the second set of signals, such that the second signal is in quadrature with the first signal over an interval.
